(19) United States
(12) Patent Application Publication
(10) Pub. No.: US 2021/0011051 A1
(43) Pub. Date: Jan. 14, 2021

(54) PIEZOELECTRIC ACCELERATION SENSOR

(71) Applicant: FATRI (Xiamen) Technologies, Co., Ltd., Xiamen City (CN)

(72) Inventors: Yongzhong Nie, Xiamen City (CN); Chengxu Luo, Xiamen City (CN)

(21) Appl. No.: 16/861,308

(22) Filed: Apr. 29, 2020

(30) Foreign Application Priority Data
Jul. 8, 2019 (CN) 2019210574157

(51) Int. Cl. G01P 15/09; H01L 41/113

(52) U.S. Cl. CPC G01P 15/09; H01L 41/1132

(57) ABSTRACT

The present application relates to a piezoelectric acceleration sensor, comprising a base member that comprises a supporting part provided with a mounting hole extending along an axis thereof and a columnar connection part located on the connection part; a piezoelectric member, sleeved outside the connection part, and defining with the connection part an annular clearance therebetween; a mass block member, sleeved outside the piezoelectric member in a gapless manner; a pre-tightening member, being a wedge block with a thinner end near the supporting part and inserted into the annular clearance; a locking member that comprises an interconnected columnar part and stopping part; wherein, the columnar part is fitted with the mounting hole for locking the above members, and the stopping part is arranged to press the first end; the columnar part and the mounting hole are provided with fastening glue arranged between.

### CROSS REFERENCE

This disclosure is based upon and claims priority to Chinese Patent Application No. 2019210574157, filed on Jul. 8, 2019, titled “ PIEZOELECTRIC ACCELERATION SENSOR”, and the entire contents of which are incorporated herein by reference.

### TECHNICAL FIELD

The present application relates to the field of sensor technology, particularly to a piezoelectric acceleration sensor.

### BACKGROUND

Piezoelectric sensors work on the basis of the piezoelectric effect of some dielectric materials, which realizes mutual conversion between mechanical energy and electrical energy. The piezoelectric sensor is widely used, among which those used to measure acceleration is called a piezoelectric acceleration sensor.

The existing piezoelectric acceleration sensor is mainly composed of a piezoelectric member, a mass block member, a pre-stressed spring, a base member and a casing. When used, the piezoelectric acceleration sensor is fixed on an object to be measured, and when the piezoelectric acceleration sensor is subjected to shock vibration together with the measured object, the piezoelectric member is subject to the inertial force of the mass block member, the inertial force acts on the piezoelectric member, the piezoelectric member generates electric charges, and the output charges are proportional to the acceleration. Therefore, the acceleration can be known according to the output charges of the acceleration sensor.

In the prior art, the Chinese patent document CN208459424U discloses a charge output element and an annular shear type piezoelectric acceleration sensor, wherein a locking member and a connection part are in threaded connection, but the piezoelectric acceleration sensor is frequently subjected to continuous vibrations and shocks when measuring acceleration, which can cause loosening of the threaded connection of the locking member, and further lead to failure of the piezoelectric acceleration sensor and poor reliability.

### SUMMARY

Therefore, the present application is to solve a technical problem that is how to overcome the deficiency of poor reliability of piezoelectric acceleration sensors in the prior arts, so as to provide a piezoelectric acceleration sensor with high reliability.

The technical solution of the present application is provided as below:

A piezoelectric acceleration sensor comprises a base member that comprises a supporting part provided with a mounting hole extending along an axis thereof and a columnar connection part located on the connection part; a piezoelectric member, sleeved outside the connection part, and defining with the connection part an annular clearance therebetween; a mass block member, sleeved outside the piezoelectric member in a gapless manner; a pre-tightening member, being a wedge block with a thinner end near the supporting part and inserted into the annular clearance; a locking member that comprises an interconnected columnar part and stopping part; wherein, the columnar part is fitted with the mounting hole for locking the above members, and the stopping part is arranged to press the first end, enabling the pre-tightening member to provide a radial pre-tightening force for fastening the piezoelectric member, the mass block member and the base member; the columnar part and the mounting hole are provided with fastening glue arranged between.

The mounting hole has a wall provided with a groove extending in a direction parallel with an axis of the mounting hole, and the fastening glue is arranged in the groove.

The piezoelectric acceleration sensor comprises at least two grooves evenly arranged.

The supporting part is provided with a vent hole communicated with the mounting hole, and gases and the fastening glue are able to be discharged from the mounting hole through the vent hole.

The locking member is subjected to heat treatment prior to being connected with the mounting hole.

The pre-tightening member has an inner ring surface of a circular truncated cone shape with a slope gradient of 86-88 degree.

The piezoelectric acceleration sensor further comprises an insulating sheet arranged at a lower side of the base member for isolating the base member from a holder for the base member to be mounted thereon.

The insulating sheet is integrally arranged with the base member.

The piezoelectric acceleration sensor further comprises a shielding case connected with the insulating sheet, the shielding case has an accommodating chamber for all of the piezoelectric member, the mass block member, the pre-tightening member and the fastening member provided on an inner side thereof, and a thunderstrike-proof circuit board provided on an outer side thereof.

The piezoelectric acceleration sensor further comprises a signal conditioning circuit board connected with the piezoelectric member, the signal conditioning circuit board is glued on the mass block member and connected with the thunderstrike-proof circuit board.

The technical solutions of the present application have the following advantages:

1. The piezoelectric acceleration sensor of the present application comprises a base member, a piezoelectric member, a mass block member, a pre-tightening member, and a locking member, the base member comprises a supporting part and a columnar connection part located on the supporting part, the connection part is provide with a mounting hole extending along an axis thereof the locking member comprises an interconnected columnar part and stopping part; during mounting, the columnar part is fitted with the mounting hole for locking all of the base member, the piezoelectric member, the mass block member, the pre-tightening member and the locking member, the pre-tightening member is a wedge block inserted into an annular clearance defined by the piezoelectric member and the connection part, and is pressed by the stopping part, achieving a tight connection between the piezoelectric member and the mass block member.

When in use, the piezoelectric member is subjected to the inertial force of the mass block member to generate electric charge. Since the piezoelectric acceleration sensor often has continuous vibration and impact, when measuring the acceleration; fastening glue provided between the columnar part and the mounting hole is able to ensure the reliability of the connection between the columnar part and the mounting hole, which may prevent the locking member and the pre-tightening member from loosening due to continuous vibration and impact during use of the piezoelectric acceleration sensor, so as to avoid of failure of piezoelectric acceleration sensor. Therefore, high reliability of piezoelectric acceleration sensor can be achieved.

2. In the piezoelectric acceleration sensor of the present application, the wall of the mounting hole is provided with a groove for the fastening glue to be provided therein, the locking member is in threaded connection with the pre-tightening member, and connected with the groove via the fastening glue. And because a clearance exists in ordinary threaded connection, when pressed, the fastening glue is squeezed into the clearance, rendering tight connection between the locking member and the pre-tightening member, and the groove extends in a direction parallel to the axis of the mounting hole, facilitating processing and increases the connection area.

3. In the piezoelectric acceleration sensor of the present application, when pressed, the fastening glue is squeezed into the clearance, there are at least two grooves which are evenly arranged, so that the fastening glue can be completely squeezed into the clearance of the thread, thus a firmer connection is achieved between the locking member and the pre-tightening member.

4. In the piezoelectric acceleration sensor of the present application, the supporting part is provided with a vent hole communicated with the mounting hole from which gases and the fastening glue are able to be discharged through the vent hole. It can effectively avoid the case where redundant fastening glue and gases make the locking member and the pre-tightening member difficult to be connected.

5. In the piezoelectric acceleration sensor of the present application, the locking member is subjected to heat treatment prior to being connected with the mounting hole, which is beneficial for improving the mechanical performance of the locking member and prevent deformation during the process of tweaking the locking member or the process of working.

6. In the piezoelectric acceleration sensor of the present application, the pre-tightening member has an inner ring surface of a circular truncated cone shape with a slope gradient of 86-88 degree. When the stopping part applies a certain force to the wedge block, the wedge block is easier to be inserted into the annular clearance, when the angle is larger. After analysis, the piezoelectric acceleration sensor has best performance when the slope of the circular truncated cone is 86-88 degree.

7. In the piezoelectric acceleration sensor of the present application, the integrally arrangement of the insulating sheet and the base member can facilitate subsequent installation.

8. The piezoelectric acceleration sensor of the present application comprises a shielding case and a thunderstrike-proof circuit board, the shielding case is used to resist external electromagnetic noise, and the thunderstrike-proof circuit board is used to suppress surge voltage, allowing the piezoelectric acceleration sensor to have a thunderstrike-proof function.

9. The piezoelectric acceleration sensor of the present application comprises a signal conditioning circuit board which is connected with the piezoelectric member and is capable of handling tiny charges generated by the piezoelectric member.

### BRIEF DESCRIPTION OF THE DRAWINGS

In order to make a clearer description of technical solutions in specific implementations of the present invention or prior art, drawings involved in description for the specific implementations or the prior art will be briefly introduced, and apparently, the drawings described below illustrate some implementations of the present invention, for one with ordinary skill in the art, other drawings can also be obtained in accordance with these drawings without delivering creative efforts.

FIG. 1 is a view of a piezoelectric acceleration sensor;

FIG. 2 is an explosive view of the piezoelectric acceleration sensor.

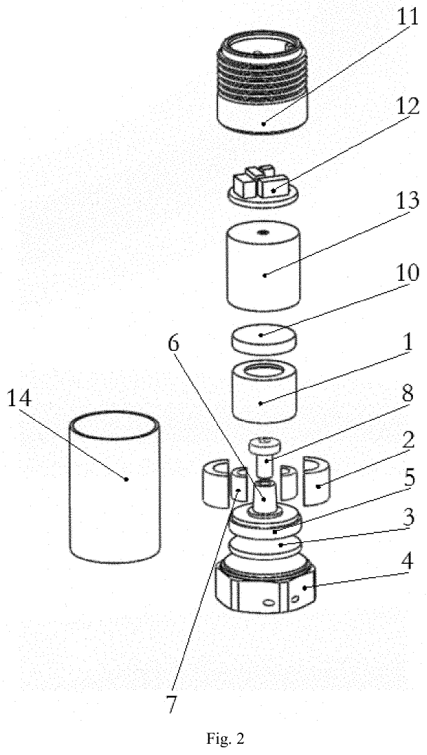

### DESCRIPTION FOR REFERENCE NUMERALS

1—mass block member; 2—piezoelectric member; 3—insulating sheet; 4—holder; 5—supporting part; 6—connection part; 7—wedge block; 8—locking member; 9—groove; 10—signal conditioning circuit board; 11—high voltage resistant two-core connector; 12—thunderstrike-proof circuit board; 13—shielding case; 14—casing.

### DETAILED DESCRIPTION

Technical solutions of the present application will be described clearly and completely as follows in conjunction with the drawings, apparently, the described embodiments are just part rather than all embodiments of the present application. Based on the embodiments in the present application, all other embodiments obtained by one with ordinary skill in the art without delivering creative efforts shall fall into the protection scope of the present application.

Moreover, technical features involved in different implementations described in the present application below may be combined with each other as long as no conflicts occur therebetween.

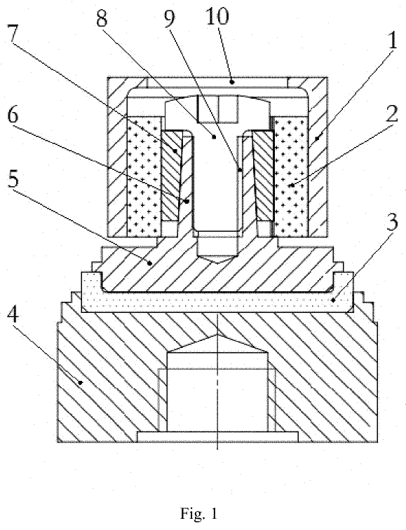

The piezoelectric acceleration sensor in this embodiment, as shown in FIG. 1, comprises a base member, a holder 4, a piezoelectric member 2, a mass block member 1, a pre-tightening member, and a locking member 8.

The base member comprises a supporting part 5 and a columnar connection part 6 located the supporting part 5, the base member is in rigid connection with the holder 4 via an insulating sheet 3, contact surfaces among the connection part 6, the base member and the holder 4 are integrated into one-piece using a ceramic welding process. The insulating sheet 3 isolates the holder 4, the piezoelectric member 2, the mass block member 1, the pre-tightening member and the locking member 8 from the sensor base member, allowing a sufficient creepage distance therebetween. The insulating sheet involved in this embodiment is aluminum oxide ceramic, and the piezoelectric member is piezoelectric ceramic.

The connection part 6 is provided with a mounting hole formed extending along the axis of the connection part 6; the piezoelectric member 2 is sleeved outside the connection part 6, an annular clearance is formed between the piezoelectric member 2 and the connection part 6, the mass block member 1 is sleeved outside the piezoelectric member 2 in a gapless manner; the pre-tightening member is inserted into the annular clearance formed between the piezoelectric member 2 and the connection part 6, the pre-tightening member is a wedge block 7 that comprises a first end and a second end and the second end is arranged to be close to the supporting part 5, and the first end have a thickness larger than that of the second end;

The locking member 8 comprises an interconnected columnar part and a stopping part, the columnar part is fitted with the mounting hole for locking the above elements, and the stopping part is arranged to press the first end, enabling the pre-tightening member to provide a radial pre-tightening force for fastening the piezoelectric member 2, the mass block member 1 and the base member. The locking member 8 is subjected to heat treatment prior to being connected with the mounting hole, which is beneficial for improving the mechanical performance of the locking member 8 and prevent deformation during the process of tweaking the locking member or the process of working.

An inner ring surface of the pre-tightening member is of a circular truncated cone shape with a slope gradient of 86-88 degree. When the slope gradient is too large, after analysis, when the stopping part applies a certain force to the wedge block 7, the easier the wedge block 7 is easier to be inserted into the annual clearance, when the angle is larger, and after practical measurement, when the slope of the circular truncated cone is 86-88 degree, the piezoelectric acceleration sensor has the best performance.

A wall of the mounting hole is provided with two grooves 9 which are evenly arranged, the groove 9 extends in a direction parallel to the axis of the mounting hole, facilitating manufacturing. The fastening glue is arranged in the grooves 9, the supporting part 5 is provided with a vent hole communicated with the mounting hole, and gases and the fastening glue are able to be discharged from the mounting hole through the vent hole.

The piezoelectric acceleration sensor further comprises a shielding case 13 and a thunderstrike-proof circuit board 12; the shielding case 13 is provided with a lead hole in the centre on the top thereof, and has an accommodating chamber for all of the piezoelectric member 2, the mass block member 1, the pre-tightening member and the fastening member, which is provided on an inner side thereof, and the thunderstrike-proof circuit board 12 is arranged on an outer side of the shielding case 13; the shielding case 13 is enclosed to resist external electromagnetic noise. The main components of the thunderstrike-proof circuit board 12 comprise a TVS tube, a gas discharge tube and a resistor. The TVS tube is used to suppress the surge voltage at 22V. The gas discharge tube is used to absorb large currents inputted from the outside. The resistor is used to absorb residual voltage, so that the piezoelectric acceleration sensor has a thunderstrike-proof function.

The piezoelectric acceleration sensor also complies a first casing 14 which has a hollow cylindrical structure with one end welded to the one-piece structure and the other end welded to a high-voltage resist two-core connector 11.

The piezoelectric acceleration sensor also complies a high-voltage resist two-core connector 11 with a casing 14 made of stainless steel, and the PIN pin and the casing 14 are connected by glass sintering to ensure sufficient creepage distance between two PIN pins and between the PIN pin and the casing 14 of the connector, so that no spark or flashover occur between the PIN pins and the outer casing 14 of the connector.

During installation, the contact surfaces between the connection part 6, the base member and the holder 4 are integrated into a one-piece structure using a ceramic welding process. The wedge block 7, the piezoelectric member 2 and the mass block member 1 are mounted on the one piece structure, and the columnar part is screwed into the mounting hole for securing the base member, the piezoelectric member 2, the mass block member 1, the pre-tightening member and the locking member 8. Because the pre-tightening member is a wedge block 7 inserted into the annular clearance formed between the piezoelectric member 2 and the connection part 6, when the locking member 8 is screwed into the mounting hole, the wedge block 7 is pressed by the stopping part to conduct longitudinal and lateral movement along an outer ring surface of the connection part 6, enabling the piezoelectric ceramic to expand under pressing by the wedge block 7 and the connection part 6, the wedge block 7 and the mass block member 1 to press each other, the fastening glue is arranged in the grooves 9, the locking member 8 is in threaded connection with the pre-tightening member, and is connected with the grooves 9 via the fastening glue, and because a clearance exists in ordinary threaded connection, when pressed, the fastening glue is squeezed into the clearance, the vent hole can effectively reduce the difficulty of connection between the locking member 8 and the pre-tightening member due to redundant fastening glue and gases. Therefore, the very tight connection between the locking member 8 and the pre-tightening member can be achieved, so that the piezoelectric member 2 and the connection part 6 are tightly connected, which improves the frequency response characteristics and resonance of the piezoelectric sensor.

Furthermore, the signal conditioning circuit board 10 which is capable of handling tiny electric charges generated by the piezoelectric member 2 is bonded to the mass block member 1 using glue. A wire which leads from the signal conditioning circuit board 10 passes through a lead hole of the shielding case 13, and is electrically connected with the thunderstrike-proof circuit board 12, and then welds the shielding case 13 with the one-piece structure together.

Finally, the high-voltage resist two-core connector 11 is fixedly connected to the casing 14.

In use, the base member is fixedly mounted on a device to be tested, and the piezoelectric member 2 is subjected to the inertial force of the mass block member 1 to generate an electric charge. Since the piezoelectric acceleration sensor often has continuous vibration and impact when measuring the acceleration, fastening glue is usually provided between the columnar part and the mounting hole, which may prevent the locking member and the pre-tightening member from loosening due to continuous vibration and impact during use of the piezoelectric acceleration sensor, so as to avoid of failure of piezoelectric acceleration sensor. Therefore, high reliability of piezoelectric acceleration sensor can be achieved.

Obviously, the above embodiments are merely intended to clearly illustrate rather than limit the numerated implementations. For one with ordinary skill in the art, other different forms of modifications or changes may further be made on the basis of the

aforementioned descriptions. It is unnecessary and impossible to exhaust all implementations. And modifications or changes derived herefrom obviously fall into the protection scope of the present invention.

What is claimed is:

1. A piezoelectric acceleration sensor, comprising:
a base member, comprising a supporting part provided with a mounting hole extending along an axis thereof and a columnar connection part located on the connection part;
a piezoelectric member, sleeved outside the connection part, and defining with the connection part an annular clearance therebetween;
a mass block member, sleeved outside the piezoelectric member in a gapless manner;
a pre-tightening member, being a wedge block with a thinner end near the supporting part and inserted into the annular clearance;
a locking member, comprising an interconnected columnar part and stopping part,
wherein,
the columnar part is fitted with the mounting hole for locking the above members, and the stopping part is arranged to press the first end, enabling the pre-tightening member to provide a radial pre-tightening force for fastening the piezoelectric member, the mass block member and the base member;
the columnar part and the mounting hole are provided with fastening glue arranged between.

2. The piezoelectric acceleration sensor according to claim 1, wherein, the mounting hole has a wall provided with a groove extending in a direction parallel with an axis of the mounting hole, and the fastening glue is arranged in the groove.

3. The piezoelectric acceleration sensor according to claim 2, comprising at least two grooves evenly arranged.

4. The piezoelectric acceleration sensor according to claim 2, wherein, the supporting part is provided with a vent hole communicated with the mounting hole, and gases and the fastening glue are able to be discharged from the mounting hole through the vent hole.

5. The piezoelectric acceleration sensor according to claim 1, wherein, the locking member is subjected to heat treatment prior to being connected with the mounting hole.

6. The piezoelectric acceleration sensor according to claim 1, wherein, the pre-tightening member has an inner ring surface of a circular truncated cone shape with a slope gradient of 86-88 degree.

7. The piezoelectric acceleration sensor according to claim 1, further comprising an insulating sheet arranged at a lower side of the base member for isolating the base member from a holder for the base member to be mounted thereon.

8. The piezoelectric acceleration sensor according to claim 7, wherein, the insulating sheet is integrally arranged with the base member.

9. The piezoelectric acceleration sensor according to claim 1, further comprising a shielding case, connected with the insulating sheet, wherein, the shielding case has an accommodating chamber for all of the piezoelectric member, the mass block member, the pre-tightening member and the fastening member provided on an inner side thereof, and a thunderstrike-proof circuit board provided on an outer side thereof

10. The piezoelectric acceleration sensor according to claim 9, further comprising a signal conditioning circuit board, connected with the piezoelectric member and the thunderstrike-proof circuit board, and glued on the mass block member.

11. The piezoelectric acceleration sensor according to claim 2, wherein, the locking member is subjected to heat treatment prior to being connected with the mounting hole.

12. The piezoelectric acceleration sensor according to claim 2, wherein, the pre-tightening member has an inner ring surface of a circular truncated cone shape with a slope gradient of 86-88 degree.

13. The piezoelectric acceleration sensor according to claim 3, wherein, the pre-tightening member has an inner ring surface of a circular truncated cone shape with a slope gradient of 86-88 degree.

14. The piezoelectric acceleration sensor according to claim 4, wherein, the pre-tightening member has an inner ring surface of a circular truncated cone shape with a slope gradient of 86-88 degree.

15. The piezoelectric acceleration sensor according to claim 2, further comprising an insulating sheet arranged at a lower side of the base member for isolating the base member from a holder for the base member to be mounted thereon.

16. The piezoelectric acceleration sensor according to claim 3, further comprising an insulating sheet arranged at a lower side of the base member for isolating the base member from a holder for the base member to be mounted thereon.

17. The piezoelectric acceleration sensor according to claim 4, further comprising an insulating sheet arranged at a lower side of the base member for isolating the base member from a holder for the base member to be mounted thereon.

18. The piezoelectric acceleration sensor according to claim 2, further comprising a shielding case, connected with the insulating sheet, wherein,
the shielding case has an accommodating chamber for all of the piezoelectric member, the mass block member, the pre-tightening member and the fastening member provided on an inner side thereof, and a thunderstrike-proof circuit board provided on an outer side thereof.

19. The piezoelectric acceleration sensor according to claim 3, further comprising a shielding case, connected with the insulating sheet, wherein,
the shielding case has an accommodating chamber for all of the piezoelectric member, the mass block member, the pre-tightening member and the fastening member provided on an inner side thereof, and a thunderstrike-proof circuit board provided on an outer side thereof.

20. The piezoelectric acceleration sensor according to claim 4, further comprising a shielding case, connected with the insulating sheet, wherein,
the shielding case has an accommodating chamber for all of the piezoelectric member, the mass block member, the pre-tightening member and the fastening member provided on an inner side thereof, and a thunderstrike-proof circuit board provided on an outer side thereof.
